(19) United States
(12) Patent Application Publication
(10) Pub. No.: US 2008/0149371 A1
(43) Pub. Date: Jun. 26, 2008

(54) Flexible circuit

(75) Inventor: Jeremy Schrooten, Mission (CA)

Correspondence Address: SCHWEGMAN, LUNDBERG & WOESSNER, P.A., P.O. BOX 2938, MINNEAPOLIS, MN, 55402, US

(73) Assignee: Angstrom Power Inc.

(21) Appl. No.: 11/644,548

(22) Filed: Dec. 22, 2006

(51) Int. Cl. H05K 1/03; H05K 1/09; H05K 1/00; H05K 3/20

(52) U.S. Cl. 174/254; 29/831

(57) ABSTRACT

A flexible circuit is formed from a dielectric core sheet and one or more patterned conductive sheets coupled to the dielectric core sheet. The patterned conductive sheets form conductive paths. In one embodiment, one or two flexible patterned graphite sheets are laminated onto the dielectric core sheet. Electrical contact may be established between the sheets through vias in the core.

### BACKGROUND

Flexible circuits are useful in many different devices, such as portable electronics, sensors, or other devices, such as electromechanical devices. Some devices need connectors that curve in order to make proper connections. Flexible printed circuits are typically fabricated using conventional techniques, relying primarily on selective removal of conductive cladding from a flexible substrate, drilling of holes to form interconnecting via's and subsequent plating of the resultant composite structure to build up conductive layers that can carry sufficient currents, and to fill the formed vias to form conductive pathways. These processes all are based on metal deposition, chemical removal and electroplating, with some potentially hazardous materials used in the manufacturing process. With increasing restrictions on the use of hazardous materials in the manufacture of electronics components there is a need for flexible circuit technology that does not rely on these hazardous circuit forming technologies.

Some environments where such flexible circuits may be used are highly corrosive. Therefore, the metal circuits formed using conventional flexible printed circuit technology degrades rapidly and cannot deliver required durability. Use of alternative materials to metals as a basis for conductive traces for circuits has so far been unsuccessful. Deposition techniques, such as depositing carbon have been tried, but result in very thin layers. Flexible circuits may also need to carry significant currents, complicating the ability to use deposition techniques. Deposition methods also complicate the formation of vias or through-hole connections for double sided or multi-layered conductive structures.

### BRIEF DESCRIPTION OF THE DRAWINGS

FIG. 1 is a perspective exploded view of a flexible circuit prior to assembly and having a dielectric core material according to an example embodiment.

FIG. 2 is a perspective view of the flexible circuit of FIG. 1 after assembly according to an example embodiment.

FIG. 3 is a cross sectional component view of the flexible circuit of FIG. 1 according to an example embodiment.

FIG. 4 is a cross sectional view of the flexible circuit of FIG. 2 according to an example embodiment.

FIG. 5 is a top view representation of a patterned sheet for use in a flexible circuit according to an example embodiment.

FIG. 6 is a perspective exploded view of a multi-layer flexible circuit prior to assembly according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

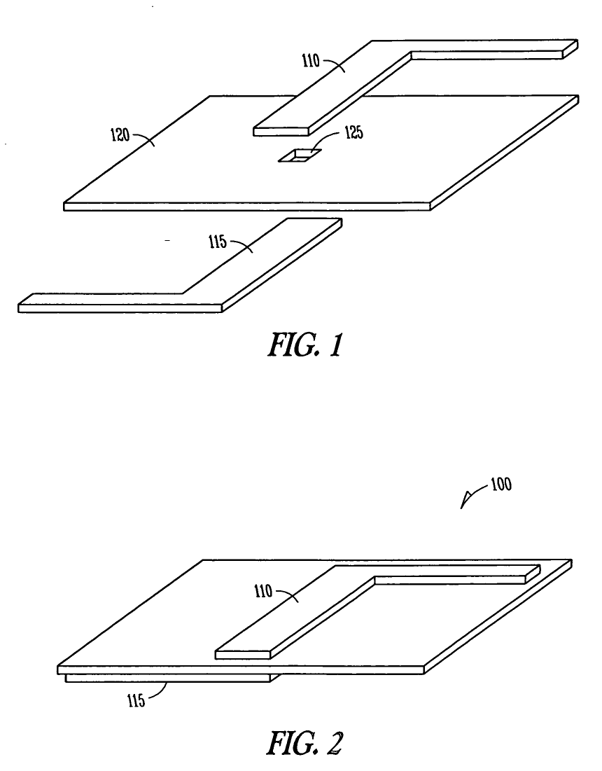

A flexible circuit 100 is produced by forming conductive paths suitable for carrying electrical current signals with good efficiency on multi-layered structures formed from flexible dielectric sheets as illustrated in FIGS. 1, 2, 3 and 4 which show various component and assembled views of an example embodiment. In some embodiments, the flexible circuit 100 is created by forming at least one layer of a conductive material into a spatially distributed collection of conductive traces which are then attached to a flexible dielectric backing to form a flexible circuit.

In one embodiment, one or two flexible patterned graphite sheets 110, 115 are laminated to a flexible dielectric core material 120. Suitable dielectric core materials 120 include various polymers that are formed in relatively thin sheets. Examples include polyester, polyethylene, polyimide, etc. In some embodiments, the dielectric core is a solid sheet.

Optionally, the dielectric sheet may be formed to conform to an irregular shape, including high aspect ratio forms, or forms involving corners, curves etc. so that the formed circuit will conform to the requirements of a particular application. The flexible circuit can be formed to sit into a device in a manner that is similar to the way a wiring harness is used with conventional wiring technology. Additionally, the dielectric sheet may include small apertures 125 that will allow conductive components on either side to be brought into electrical contact. These apertures 125 are also referred to as vias 125.

The dielectric sheet may alternatively be made of a composite material, for instance it may be a lamination of several layers of material to provide a composite sheet with the required dielectric properties. In one embodiment, dimensional stability and tensile strength may be added through the embedding of fibers, such as a fiber mesh layer between thin dielectric sheets. The fibers may be nanofibers, such as carbon nanofibers or nanotubes, or other types of small or larger fibers which result in a sheet having the desired properties.

In a similar manner, fabrics may be modified so that the inventive circuit technology can be formed directly onto the modified fabrics for embedding electronic circuits into furniture, automotive interiors, clothing and the like. Such fabrics may include common clothing and upholstery type fabrics formed in such a manner as to retain suitable dielectric properties. The use of such fabrics may provide desired tensile strength, but may also be done simply to incorporate electronics into fabrics for use in a multitude of products.

Vias 125 may be formed to any dimension called for by the application and using any fabrication method suited to making these apertures in the selected dielectric or dielectric composite sheet. Small circular vias can be made as small as 25 microns in diameter or smaller using die punching or mechanical or laser milling. Various etching techniques can also be used in conjunction with a mask when the density of vias is very high. Irregular shaped vias such as rectangular vias, long slit vias or elliptical vias can also be formed using these methods. An aspect of some embodiments of forming irregular shaped vias is the inclusion of rounded corners so as to avoid large stress concentrations building up in the dielectric material if the resulting circuit is placed under stress.

Suitable conductive materials for use as a patterned graphite sheet 110, 115 include conductive graphite or expanded graphite sheets. These materials have the property of high electrical conductivity while at the same time are reasonably “compressible” initially. In addition, these materials are available as sheets in pre-determined thicknesses between 25 and 5,000 microns so that the eventual current carrying capacity of the formed circuit traces can be selected by choosing an appropriate thickness of the material in conjunction with trace width, which may be constrained due to other aspects of the application. Examples of materials include but are not limited to Grafoil® GRAFTECH INC. CORPORATION DELAWARE 11709 MADISON AVENUE LAKEWOOD Ohio 44107, Crane-foil® JOHN CRANE INC. CORPORATION DELAWARE 6400 Oakton St. Morton Grove Ill. 60053, SIGRAFLEX® Sigri Elektrographit GmbH joint stock company with limited liability FED REP GERMANY Werner-von-Siemens Strasse 18 Meitingen FED REP GERMANY 8901, and Aiflon® Sigri Elektrographit GmbH joint stock company with limited liability FED REP GERMANY Werner-von-Siemens Strasse 18 Meitingen FED REP GERMANY 8901.

In some embodiments, composite conductive materials such as carbon filled epoxies could also be used. These are available in sheet form, and also can be created in ‘preforms’ which would define the desired pattern of conductive traces during the fabrication process. An example of this sort of material is TFE2213F available from TECHFILM 31 Dunham Rd Billerica, Mass. 01821.

The conductive layers are patterned to form conductive traces as illustrated at 110, 115 which are then to be overlaid onto the dielectric core. Methods of forming the conductive traces include die punching, mechanical converting, laser ablation, oxidative etching or other methods of micromachining. Using these techniques with some of the materials described it has been shown that traces as narrow as about 25 microns with spaces between traces of as little of about 25 microns can be achieved. Smaller minimum trace and gap widths may be possible with the use of oxidative etching or refined laser ablation techniques. Very large sizes of traces may be achievable, and arbitrary shapes and path lengths for traces may also be achieved.

At least one conductive trace is applied to at least one side of at least one dielectric core. In practice, many conductive traces can be applied to many dielectric cores, which are then laminated to form a multi-layered structure. The layers are first assembled with geometric alignment. Examples of alignment options include but are not limited to specific alignment features, pin jigs, and optical alignment.

Once aligned, the parts are laminated together. Depending on the nature of the dielectric core, the lamination may either done by hot pressing at a temperature approaching the glass transition temperature of the dielectric core, or alternatively the dielectric core may be abraded so as to make the surface rough allowing a mechanical bond to be formed. Examples of methods of lamination include, but are not limited to hot pressing, cold pressing, axial pressing, isostatic pressing, roll pressing, and combinations thereof.

In some embodiments, an epoxy or an adhesive may be used to enhance the bond between the dielectric core and the conductive layer. These materials are available in sheet form and may be patterned and aligned to match up with the conductive layer. These materials are also available in a curable liquid form wherein the desired pattern can be defined using any known liquid deposition technique, including but not limited to syringe injection, screen printing, and painting. Such adhesives or epoxies may be non-conductive and may be used to enhance the bond between the dielectric core and the conductive layer.

Conductive adhesives and epoxies are also available and may be used not only to enhance the mechanical bond between the dielectric core and the conductive layer but may also serve to increase electrical conductivity. In some embodiments, the epoxy or adhesive may be used proximate the vias, such as in or through the vias to achieve better through-via conductivity in embodiments where more than one conductive layer may be disposed on either side of a dielectric core. An example of this sort of material is EP75-1 available from MASTER BOND, INC. 154 Hobart St Hackensack, N.J. 07601.

In one example, circuit traces formed from expanded graphite are bonded to a polyester dielectric core by hot pressing at 3000 psi and 140° C.; conditions which are sufficient to achieve a robust bond between the expanded graphite and the polyester. The pressures and temperatures may vary depending on the materials and desired bond. For example, polyimide does not have a glass transition temperature. When it is used as the dielectric core, the surfaces of it may need to be mechanically abraded so that a mechanical bond can be formed with the graphite during lamination. Sandpaper may be used in one embodiment. Other forms of abrasion may also be used, including non-mechanical means. When conductive epoxies are used as the conductive traces, the epoxy can bond directly to the dielectric core with no pretreatment or elevated temperature required for the lamination.

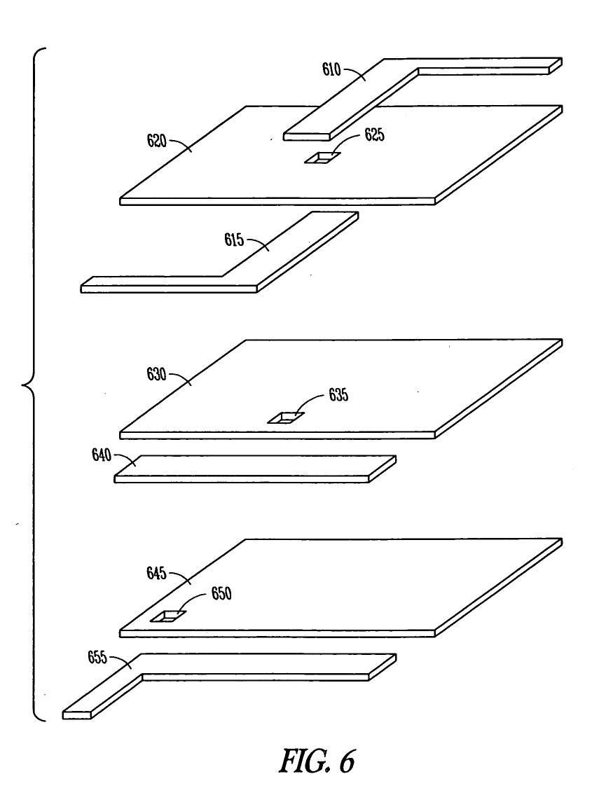

In one simple embodiment, as illustrated in FIG. 5, multiple conductive paths are formed from a graphite sheet 510. For ease of conveying the concepts, only a few paths are shown. In further embodiments, much more complex patterning of the graphite sheets may be utilized. A first path 515 traverses the sheet uninterrupted. A second path 520 begins at a first side 525 of the sheet and ends about half way across the sheet. A third path 530 traverses only a lower portion of the sheet and a third path 540 traverses the sheet uninterrupted. Multiple vias may be used to connect through to one or more other patterned sheets.

In one embodiment, several structural connections, all referenced as 550, remain during patterning of the sheet and connect the paths to provide structural integrity for the pattern formed by the paths for transfer to the dielectric core. These structural connections electrically connect all of the conductive paths, thus creating a potential short-circuit condition if not removed before completion of the circuit. The structural connections may be removed by mechanical cutting or by laser or otherwise removed after the pattern has been aligned on or pressed onto the core. The number and placement of the structural connections 550 may be determined to provide adequate structural support to allow proper alignment of the pattern on the core without adversely disturbing the pattern.

In further embodiments, the pattern may be formed without the structural connections. The pattern may then be transferred using a transfer sheet that lightly adheres to the pattern and allows proper alignment on the core without adversely disturbing the pattern.

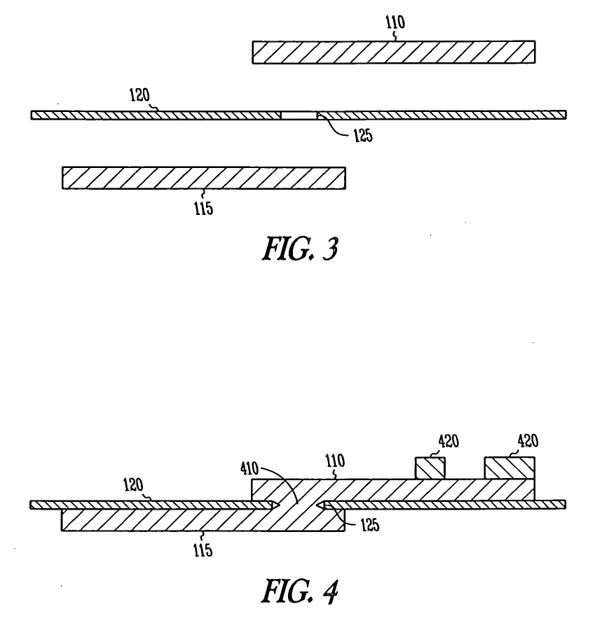

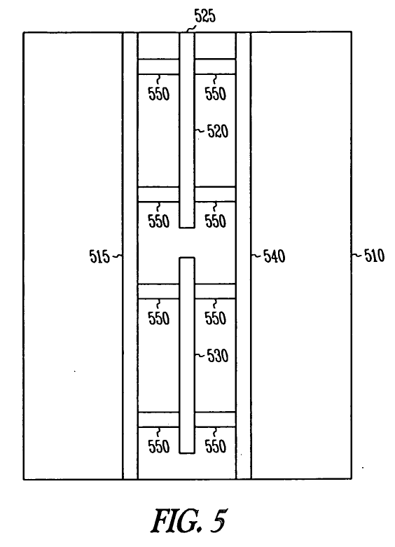

The lamination step has at least two side effects as illustrated in FIGS. 3 and 4. First, the conductive material is forced into the dielectric layer creating a mechanical bond. Second, when a connection through the dielectric layer is desired, it forces the conductive material through the vias 125, whereupon a conductive material to conductive material bond is formed at 410 creating through-plane conductivity. Once cooled, the composite circuit has good electrical conductivity, appropriate through-plane electrical connections and remains flexible and resistant to corrosion. Electrical connections to other devices 420 can then be formed using conductive adhesives, allowing the flexible circuit to additionally function as a circuit board with mounted components. Examples of adhesives include but are not limited to silver filled epoxy, carbon filled epoxy, gold filled epoxy, silver filled pressure sensitive adhesive, carbon filled pressure sensitive adhesive, and gold filled pressure sensitive adhesive.

FIG. 6 is a perspective exploded view of a multi-layer flexible circuit 600 prior to assembly according to an example embodiment. When multiple layers of circuitry are required, the technique is easily extended by forming a multi-layer structure consisting of alternating layers of conductive traces and dielectric cores, then laminating these together as previously described. Note it is not required to complete the entire multi-layered circuit in one lamination step; multiple laminations can be used to ‘build up’ the required multi-level structure. The formation of via's as described can be used to allow forming of conductive pathways between arbitrary layers of the multi-layer structure.

In one embodiment, two flexible patterned conductive sheets 610, 615 are laminated to a flexible dielectric core material 620. Suitable dielectric core materials 620 include various polymers that are formed in relatively thin sheets. Examples include polyester, polyethylene, polyimide, etc. In some embodiments, the dielectric core is a solid sheet.

Optionally, the dielectric sheet may be formed to conform to an irregular shape, including high aspect ratio forms, or forms involving corners, curves etc. so that the formed circuit will conform to the requirements of a particular application. The flexible circuit can be formed to sit into a device in a manner that is similar to the way a wiring harness is used with conventional wiring technology. Additionally, the dielectric sheet 620 may include small apertures 125 that will allow conductive components on either side to be brought into electrical contact.

Circuit 600 further includes a second dielectric sheet 630 having an aperture 635, a further patterned conductive sheet 640, a third dielectric sheet 645 having an aperture 650 and a final patterned conductive sheet 655. Further layers may be added as desired. In this embodiment, when laminated, conductive sheet 640 electrically couples sheet 615 through aperture 635, and conductive sheet 655 electrically couples to sheet 640 through aperture 650. In further embodiments, conductive sheets may have multiple such connections through the dielectric sheets, or need not have any such connections. The patterning of the conductive sheets shown is rather simple for clear explanation purposes only and may be much more complex.

The circuits formed using the materials and processes described may be formed either a sheet at a time, or through ‘panels’ consisting of multiple circuits on the same sheet that are later cut out of the overall fabrication panel, or through the use of a roll-roll lamination process in which the various conductive and dielectric sheets are patterned independently and then the rolls of the sheets may be laminated together in a continuous manufacturing process, with individual circuits later cut from the roll of laminated sheets.

In one embodiment, the use of carbon based conductors reduces or eliminates the need for solvents or other environmentally damaging processes. The resulting flexible circuits may be bent to fit within various containers, such as a fuel cell based power generators, where it may be used to collect current from multiple fuel cells. In one embodiment, it may be flexed to conform to a cylindrical fuel container. The flexible circuit may also be used in many different structures and may include components that are adhered to the connectors, such that it can be used as a circuit board for myriad electronic applications.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A flexible circuit comprising:
a dielectric core sheet; and
one or more patterned conductive sheets coupled to the dielectric core sheet.

2. The flexible circuit of claim 1 wherein the dielectric core sheet is approximately 25 μm thick.

3. The flexible circuit of claim 1 wherein the dielectric core sheet has a glass transition temperature well below the temperature at which carbon exhibits oxidation.

4. The flexible circuit of claim 1 wherein the dielectric core sheet includes a material selected from the group consisting of polyester, polyethylene and polyimide.

5. The flexible circuit of claim 1 wherein the dielectric core sheet is formed to conform to a path.

6. The flexible circuit of claim 1 wherein the dielectric core sheet contains at least one via.

7. The flexible circuit of claim 1 wherein the one or more patterned conductive sheets are conductive graphite or expanded graphite sheets.

8. The flexible circuit of claim 1 wherein the one or more patterned conductive sheets are patterned to conductive traces and include alignment features.

9. The flexible circuit of claim 1 wherein the one or more patterned conductive sheets are laminated to the dielectric core sheet.

10. The flexible circuit of claim 9, wherein the one or more conductive sheets are laminated to the dielectric core sheet by a lamination method selected from the group consisting of: hot pressing, cold pressing, axial pressing, isostatic pressing, roll pressing, and combinations thereof.

11. The flexible circuit of claim 10 wherein the first and second patterned conductive sheets are bonded to each other through the vias to create through-plane conductivity.

12. The flexible circuit of claim 9, and further comprising an epoxy or an adhesive between the one or more conductive sheets and the dielectric core sheet.

13. The flexible circuit of claim 9 wherein a first patterned conductive sheet on a first side of the dielectric core is electrically coupled through vias in the dielectric core to a second patterned conductive sheet on a second side of the dielectric core sheet.

14. The flexible circuit of claim 13, and further comprising a conductive epoxy or conductive adhesive proximate the vias to enhance conductively between conductive sheets.

15. The flexible circuit of claim 9 wherein the dielectric core sheet is mechanically roughened prior to being laminated.

16. The flexible circuit of claim 1 and further comprising electrical components conductively adhered to at least one of the conductive sheets.

17. The flexible circuit of claim 1 wherein the dielectric core sheet comprises a composite material.

18. The flexible circuit of claim 17 wherein the dielectric core sheet comprises a fabric.

19. A flexible circuit comprising:
a flexible dielectric polymer core sheet having vias; and
two trace patterned conductive sheets geometrically aligned and coupled to opposite sides of the dielectric core sheet.

20. The flexible circuit of claim 19 and further comprising additional dielectric core sheets and trace patterned conductive sheets arranged in alternate layers.

21. The flexible circuit of claim 19 wherein the dielectric core sheet is approximately 25 μm thick and the vias have lengths or a diameter of approximately 100 μm.

22. A method of forming a flexible circuit, the method comprising:
patterning a first conductive flexible sheet with conductive paths; and
attaching the first conductive flexible sheet to a flexible dielectric core.

23. The method of claim 22 and further comprising:
patterning a second conductive flexible sheet with conductive paths; and
attaching the second conductive flexible sheet to the flexible dielectric core.

24. The method of claim 23 and further comprising forming vias through the flexible dielectric core.

25. The method of claim 24 wherein attaching the first and second conductive sheets to the flexible dielectric core comprises laminating the sheets to the core such that the first and second conductive sheets form electrical contacts through the vias.

26. The method of claim 25, wherein the conductive sheets are patterned graphite sheets laminated to the dielectric core sheet by a lamination method selected from the group consisting of: hot pressing, cold pressing, axial pressing, isostatic pressing, roll pressing, and combinations thereof.

27. The method of claim 26 wherein the hot pressing is performed at approximately 140° C. and 3000 psi.

28. The method of claim 23 wherein the patterned sheets include supports, wherein the patterned sheets are geometrically aligned prior to attaching and wherein the supports are rendered non-conductive after alignment.

29. A method of forming a flexible circuit, the method comprising:
patterning a first conductive flexible sheet with an individual circuit of conductive paths;
coupling the first conductive flexible sheet to a flexible dielectric core.

30. The method of claim 29 wherein multiple panels of circuits are patterned on the first conductive flexible sheet.

31. The method of claim 30 wherein multiple panels of circuits are formed in a continuous manufacturing process.

32. The method of claim 31 wherein the continuous manufacturing process comprises roll-to-roll manufacturing.

33. The method of claim 32 wherein the rolls are coupled together by lamination.

34. The method of claim 29 wherein the flexible circuit is incorporated into fabric.

35. The method of claim 34 wherein the fabric is incorporated into furniture, automotive interiors, or clothing.
